(19) United States
(12) Patent Application Publication
(10) Pub. No.: US 2024/0099101 A1
(43) Pub. Date: Mar. 21, 2024

(54) LIGHT-EMITTING DEVICE AND SEALING UNIT

(71) Applicants: PIONEER CORPORATION, Bunkyo-ku,Tokyo (JP); TOHOKU PIONEER CORPORATION, Tendo-shi, Yamagata (JP)

(72) Inventors: Masaki TAKAHASHI, Yonezawa-shi, Yamagata (JP); Shinji NAKAJIMA, Yonezawa-shi, Yamagata (JP)

(21) Appl. No.: 17/909,724

(22) PCT Filed: Feb. 8, 2021
(86) PCT No.: PCT/JP2021/004528

§ 371 Date: Sep. 6, 2022

(30) Foreign Application Priority Data
Mar. 5, 2020 (JP) 2020-037470

(51) Int. Cl. H10K 59/80

(52) U.S. Cl. CPC H10K 59/8722

(57) ABSTRACT

A sealing unit (200) includes a substrate unit (210) and a protruding portion (220). The protruding portion (220) protrudes from the substrate unit (210) toward a substrate (100). Further, when viewed from a thickness direction of the substrate unit (210), the protruding portion (220) has a frame shape. An outer wall (226) of the protruding portion (220) includes a recessed portion (222). The recessed portion (222) of the outer wall (226) of the protruding portion (220) is located at a corner of the frame shape of the protruding portion (220). In addition, the recessed portion (222) of the outer wall (226) of the protruding portion (220) is recessed toward an inner wall (228) of the protruding portion (220) relative to an outer edge (216) of the substrate unit (210).

### TECHNICAL FIELD

The present invention relates to a light-emitting device and a sealing unit.

### BACKGROUND ART

A light-emitting device including a light-emitting unit such as an organic electroluminescence (EL) element may include a sealing unit for sealing the light-emitting unit.

Patent Document 1 describes a sealing unit including a substrate unit and a protruding portion protruding from the substrate unit toward a substrate of the light-emitting device. This protruding portion has a frame shape when viewed from a thickness direction of the substrate unit, and is adhered to the substrate of the light-emitting device with an adhesive layer therebetween. The substrate unit of the sealing unit and the substrate of the light-emitting device are cut out by cutting. In Patent Document 1, the outer wall of the protruding portion is located inside the outer edge of the substrate unit all over the periphery of the frame shape such that a cutting line does not overlap the adhesive layer when cutting, and the adhesive layer is provided only on a top surface of the protruding portion such that the adhesive layer does not cover the outer wall of the protruding portion.

Patent Document 2 describes that the outer edge of the sealing unit is covered by the adhesive layer to improve an adhesive property between the substrate and the sealing unit.

### RELATED ART DOCUMENTS

### Patent Documents

[Patent Document 1] Japanese Unexamined Patent Application Publication No. 2006-202722
[Patent Document 2] Japanese Unexamined Patent Application Publication No. 2012-252827

### SUMMARY OF THE INVENTION

### Technical Problem

As described in Patent Document 1, when a substrate unit of a sealing unit and a substrate of a light-emitting device are cut out by cutting, in order to improve an adhesive property between the substrate and the sealing unit, an outer wall of a protruding portion of the sealing unit is preferably covered by an adhesive layer as described in Patent Document 2. However, when, in order for the outer wall of the protruding portion of the sealing unit to be covered by the adhesive layer, the outer wall of the protruding portion of the sealing unit is located inside the outer edge of the substrate unit of the sealing unit all over the periphery of the frame shape of the protruding portion while maintaining a size of the substrate unit of the sealing unit, a width of the protruding portion becomes narrow, which may deteriorate a sealing performance of the sealing unit. Further, when the outer wall of the protruding portion of the sealing unit is located inside the outer edge of the substrate unit of the sealing unit all over the periphery of the frame shape of the protruding portion by extending the outer edge of the substrate unit of the sealing unit outward while maintaining the width of the protruding portion, the size of the substrate unit of the sealing unit becomes larger, which may increase a cost of the sealing unit.

An example of a problem to be solved by the present invention is to improve an adhesive property between a substrate and a sealing unit while inhibiting deterioration of a sealing performance of the sealing unit and an increase of a cost of the sealing unit.

### Solution to Problem

The invention described in claim 1 is a light-emitting device including:
a substrate;
a light-emitting unit located over the substrate; and
a sealing unit sealing the light-emitting unit, the sealing unit including a substrate unit and a protruding portion which protrudes from the substrate unit toward the substrate, has a frame shape when viewed from a thickness direction of the substrate unit, and is adhered to the substrate with an adhesive layer therebetween,
in which an outer wall of the protruding portion includes a recessed portion which is recessed toward an inner wall of the protruding portion relative to an outer edge of the substrate unit, the recessed portion being located at a corner of the frame shape when viewed from the thickness direction of the substrate unit.

The invention described in claim 5 is a sealing unit including:
a substrate unit; and
a protruding portion which protrudes from the substrate unit toward a thickness direction of the substrate unit and has a frame shape when viewed from the thickness direction of the substrate unit,
in which an outer wall of the protruding portion includes a recessed portion which is recessed toward an inner wall side of the protruding portion and which is located at a corner of the frame shape when viewed from the thickness direction of the substrate unit.

### BRIEF DESCRIPTION OF THE DRAWINGS

FIG. 1 is a plan view of a light-emitting device according to an embodiment.

FIG. 2 is a cross-sectional view taken along line A-A of FIG. 1.

FIG. 3 is a cross-sectional view taken along line B-B of FIG. 1.

FIG. 4 is a cross-sectional view taken along line C-C of FIG. 1.

FIG. 5 is a diagram to explain one example of a method for manufacturing the light-emitting device illustrated in FIGS. 1 to 4.

FIG. 6 is a plan view of a light-emitting device according to a modification example.

### DESCRIPTION OF EMBODIMENTS

In the present specification, the expression “A is located over B” may mean that, for example, A is located directly over B without another element (for example, layer) located between A and B, or may mean that another element (for example, layer) is partly or wholly located between A and B. In addition, an expression indicating a direction such as “top”, “bottom”, “left”, “right”, “front”, and “rear” or the like is basically used in combination with a direction of a drawing, and it is not limited to be interpreted for, for example, a direction of the use of an invention described in the present specification.

In the present specification, unless otherwise noted, the expression “protruding” means an aspect of protruding from a certain surface, and it is not used to limit the aspect. For example, an aspect of “protruding” refers to protruding simply straight from a certain surface. Another aspect refers to protruding from a certain surface in a curved manner.

In the present specification, unless otherwise noted, the expression “A and B overlap” means that at least a part of A occupies the same area as at least a part of B in an image projected from a certain direction. At this time, a plurality of elements may be in contact with each other, or may be separated from each other.

In the present specification, unless otherwise noted, the expression “outside of A” means an area where A is not positioned with the edge of A as a boundary.

In the present specification, an anode indicates an electrode which injects an electron hole into a layer (for example, organic layer) including a light-emitting material, and a cathode indicates an electrode which injects an electron into a layer including the light-emitting material. Further, the expressions “anode” and “cathode” may mean other wordings such as “electron hole injection electrode” and “electron injection electrode”, or “positive electrode” and “negative electrode” or the like.

“Light-emitting device” in the present specification includes a device including a light-emitting element such as a display or illumination or the like. Further, there may be a case where a wiring directly, indirectly, or electrically connected to a light-emitting element, an integrated circuit (IC), or a housing or the like is also included in “light-emitting device”.

In the present specification, “connection” indicates a state in which a plurality of elements are being connected regardless of whether they are directly or indirectly connected. For example, a case where the plurality of elements are connected with an adhesive or a connecting member therebetween may also be expressed simply as “a plurality of elements are connected”. Further, a case where a member which is capable of supplying or transmitting current, voltage, or electrical potential exists between the plurality of elements and “the plurality of elements are electrically connected” may also be expressed simply as “a plurality of elements are connected”.

In the present specification, unless otherwise noted, expressions such as “first, second, A, B, (a), (b)” or the like are intended to distinguish an element, and an essence, an order, a sequence, a quantity, or the like of the element is not limited by the expression.

In the present specification, each member and each element may be singular, or plural. However, when “singular” or “plural” is clear in a context, it is not limited to this.

In the present specification, unless otherwise noted, a meaning of the expression “A includes B” is not limited to that A is configured only with B, but that A can be configured with elements other than B.

In the present specification, unless otherwise noted, “section” means a surface which appears when a light-emitting device is cut in a direction of a pixel or a light-emitting material or the like being laminated.

In the present specification, expressions such as “does not have”, “does not include”, and “is not located” or the like may mean that a certain element is completely excluded or that a certain element exists to a degree at which the element does not have a technical effect.

In the present specification, expressions for explaining a temporal before-after relationship, such as “after”, “subsequently to”, “next to”, and “before” or the like express a relative temporal relationship, and respective elements for which the temporal before-after relationship is used are not necessarily continuous. In order to express that the respective elements are continuous, an expression such as “immediately” or “directly” or the like may be used.

In the present specification, unless otherwise noted, the expression “substantially parallel” also includes a state of being inclined to such a degree as to have a technical effect. For example, a case where two elements A and B do not have a critically technical effect at an angle which is equal to or greater than −10 degrees and equal to or less than 10 degrees in a state where the two elements A and B are located at an angle which is equal to or greater than −10 degrees and equal to or less than 10 degrees is expressed as “A and B are substantially parallel”. A state where the two elements A and B are located at the angle which is equal to or greater than −10 degrees and equal to or less than 10 degrees by a manufacturing error is also expressed as “A and B are substantially parallel”. An expression “parallel” means that two elements are parallel in a mathematical meaning.

In the present specification, unless otherwise noted, the expression “A covers B” may mean that A is in contact with B without another element (for example, layer) located between A and B, or may mean that another element (for example, layer) is partly or wholly located between A and B.

Embodiments of the present invention will be described below by referring to the drawings. Moreover, in all the drawings, the same constituent elements are given the same reference numerals, and descriptions thereof will not be repeated.

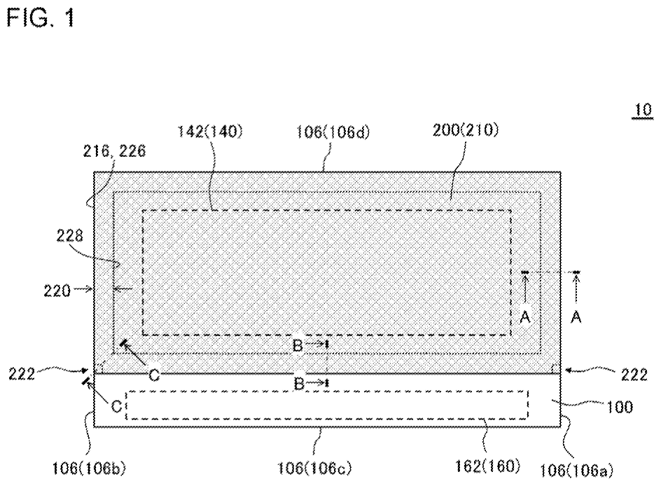

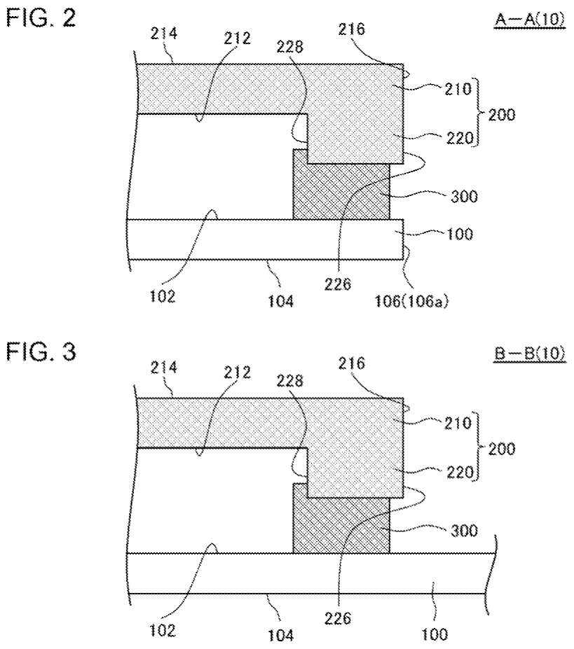

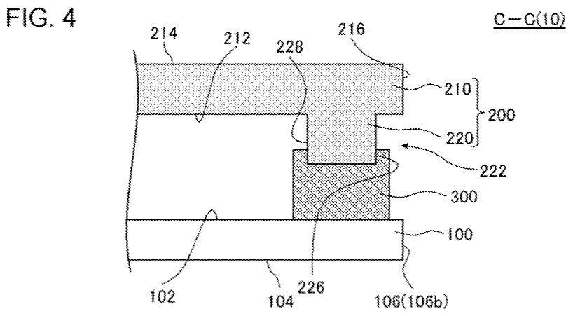

FIG. 1 is a plan view of a light-emitting device 10 according to an embodiment. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1.

A summary of the light-emitting device 10 will be explained using FIG. 1 and FIG. 4. The light-emitting device 10 includes a substrate 100, a light-emitting unit 140, and a sealing unit 200. The light-emitting unit 140 is located over the substrate 100. The sealing unit 200 seals the light-emitting unit 140. The sealing unit 200 includes a substrate unit 210 and a protruding portion 220. The protruding portion 220 protrudes from the substrate unit 210 toward the substrate 100. Further, the protruding portion 220 has a frame shape when viewed from a thickness direction of the substrate unit 210. Further, the protruding portion 220 is adhered to the substrate 100 with an adhesive layer 300 therebetween. An outer wall 226 of the protruding portion 220 includes a recessed portion 222. The recessed portion 222 of the outer wall 226 of the protruding portion 220 is located at a corner of the frame shape of the protruding portion 220. Further, the recessed portion 222 of the outer wall 226 of the protruding portion 220 is recessed toward an inner wall 228 of the protruding portion 220 relative to an outer edge 216 of the substrate unit 210.

According to the present embodiment, the outer wall 226 of the protruding portion 220 is not required to be located inside the outer edge 216 of the substrate unit 210 except the portion to which the recessed portion 222 is provided. Therefore, in comparison with a case where the outer wall 226 of the protruding portion 220 of the sealing unit 200 is located inside the outer edge 216 of the substrate unit 210 of the sealing unit 200 all over the periphery of the frame shape while maintaining the size of the substrate unit 210 of the sealing unit 200 the same as a size according to the present embodiment, it is possible to widen a width of the protruding portion 220 except the portion to which the recessed portion 222 is provided, which can inhibit a sealing performance of the sealing unit 200 from being deteriorated. Further, in comparison with a case where the outer wall 226 of the protruding portion 220 of the sealing unit 200 is located inside the outer edge 216 of the substrate unit 210 all over the periphery of the frame shape by extending the outer edge 216 of the substrate unit 210 outward while maintaining the width of the protruding portion 220 the same as the width according to the present embodiment, it is possible to make the size of the substrate unit 210 of the sealing unit 200 smaller, which can inhibit a cost of the sealing unit 200 from increasing.

Further, as a result of studies conducted by the inventors, it has become clear that a sealing unit 200 easily peels off from a substrate 100 at a corner of its frame shape. According to the present embodiment, as shown in FIG. 4, the adhesive layer 300 can cover at least a part of the portion of the outer wall 226 of the protruding portion 220, the portion being provided with the recessed portion 222. Therefore, in comparison with a case where the adhesive layer 300 does not cover the outer wall 226 of the protruding portion 220, it is possible to make an adhesive property between the substrate 100 and the sealing unit 200 high.

Details of the light-emitting device 10 will be explained using FIGS. 1 to 4.

The substrate 100 may be single-layered or multi-layered. A thickness of the substrate 100 is, for example, equal to or greater than 10 μm and equal to or less than 1,000 μm. The substrate 100 includes a first surface 102 and a second surface 104. The light-emitting unit 140, a terminal 160 (to be described in detail later), the sealing unit 200, and the adhesive layer 300 are located over the first surface 102 of the substrate 100. The second surface 104 is on the opposite side to the first surface 102. The substrate 100 is, for example, a glass substrate. The substrate 100 may be a resin substrate containing an organic material (for example, polyethylene naphthalate (PEN), polyether sulphone (PES), polyethylene terephthalate (PET), or polyimide). In a case where the substrate 100 is a resin substrate, an inorganic barrier layer (for example, SiN or SiON) may be located over at least one of the first surface 102 and the second surface 104 of the substrate 100.

The substrate 100 has a rectangular shape when viewed from a thickness direction of the substrate 100. Specifically, a side 106 of the substrate 100 includes a first side 106a, a second side 106b, a third side 106c, and a fourth side 106d. The first side 106a and the second side 106b extend substantially in parallel. The third side 106c and the fourth side 106d extend substantially in parallel and extend in a direction crossing an extending direction of the first side 106a or the second side 106b.

The light-emitting unit 140 includes an organic EL element. The organic EL element, that is, the light-emitting unit 140 includes an anode, a cathode, and an organic layer between the anode and the cathode. The anode, the organic layer, and the cathode are located over the first surface 102 of the substrate 100, and laminated in order from the first surface 102 side of the substrate 100. The organic layer includes, for example, a hole injection layer (HIL), a hole transport layer (HTL), a light-emitting layer (EML), an electron transport layer (ETL), and an electron injection layer (EIL) in this order from the anode toward the cathode. However, a configuration of layers included in the organic layer is not limited to an example explained here.

The light-emitting unit 140 has a bottom-emission structure. That is, light emitted from the light-emitting unit 140 is transmitted through the substrate 100 and irradiated toward the outside of the light-emitting device 10 from the second surface 104 side of the substrate 100. However, the light-emitting unit 140 may have a top-emission structure. Further, the light emitted from the light-emitting unit 140 may be irradiated from both of the first surface 102 side of the substrate 100 and the second surface 104 side of the substrate 100.

As shown in FIG. 1, the light-emitting device 10 includes a light-emitting region 142 and a terminal area 162. The light-emitting region 142 and the terminal area 162 are aligned along an extending direction of the first side 106a or the second side 106b of the substrate 100. Further, the terminal area 162 is located on the third side 106c side of the substrate 100 relative to the light-emitting region 142 and the sealing unit 200.

The light-emitting region 142 includes at least one light-emitting unit 140. The light-emitting region 142 is located in a region surrounded by the inner wall 228 of the protruding portion 220 of the sealing unit 200 when viewed from the thickness direction of the substrate 100. In the present embodiment, the light-emitting region 142 has a plurality of light-emitting units 140 arranged in a matrix. Therefore, the light-emitting device 10 is a light-emitting display. For example, a plurality of anodes arranged in a stripe pattern and a plurality of cathodes arranged in a stripe pattern intersect each other. In this case, an intersection portion of these anodes and cathodes is a pixel, that is, the light-emitting unit 140. However, an aspect of at least one light-emitting unit 140 provided in the light-emitting region 142 is not limited to an aspect according to the present embodiment.

At least one terminal 160 is disposed in the terminal area 162. The terminal 160 is electrically connected to the light-emitting unit 140. Specifically, the terminal area 162 includes a plurality of terminals 160 respectively connected to the plurality of anodes in the light-emitting region 142, and a plurality of terminals 160 respectively connected to the plurality of cathodes in the light-emitting region 142. In the present embodiment, the terminal 160 is provided only on one side of the light-emitting region 142, that is, only on the third side 106c side of the substrate 100, and the terminal 160 is not provided on another side of the light-emitting region 142, that is, on the fourth side 106d side of the substrate 100.

The terminal area 162 is easily subjected to force along the thickness direction of the substrate 100 in various cases, for example, a case where a wiring member such as a Flexible Printed Circuit (FPC) or the like is connected to the terminal 160 in the terminal area 162, a case where an electronic component such as a chip or the like is mounted in the terminal area 162, or a case where a worker who carries the light-emitting device 10 puts a finger on the terminal area 162. The sealing unit 200 easily peels off from the substrate 100 when the force is added along the thickness direction of the substrate 100. In the present embodiment, of the four corners of the frame shape of the protruding portion 220 of the sealing unit 200, the two corners on the terminal area 162 side are provided with the recessed portion 222. Therefore, in comparison with a case where the two corners are not provided with the recessed portion 222, it is possible to inhibit the sealing unit 200 from peeling off from the substrate 100. In contrast, of the four corners of the frame shape of the protruding portion 220 of the sealing unit 200, the two corners on the opposite side to the terminal area 162, that is, on the fourth side 106d side of the substrate 100 are not provided with the recessed portion 222. In other words, when viewed from the thickness direction of the substrate unit 210, the outer wall 226 of the protruding portion 220 includes a portion which is aligned with the outer edge 216 of the substrate unit 210 and which is located at the corners on the opposite side to the terminal area 162. At the corners, the substrate 100 is unlikely to be subjected to force along the thickness direction of the substrate 100. For this reason, even if the corners are not provided with the recessed portion 222, it does not greatly affect the adhesive property between the substrate 100 and the sealing unit 200. Further, it is possible to reduce manufacturing costs of the sealing unit 200 by an amount which is saved by not providing the recessed portion 222 at the corners.

Note that, of the four corners of the frame shape of the protruding portion 220, not both of the two corners on the terminal area 162 side need be provided with the recessed portion 222. For example, of the four corners of the frame shape of the protruding portion 220, only one of the two corners on the terminal area 162 side may be provided with the recessed portion 222.

The sealing unit 200 is formed of, for example, glass. In this example, by processing the glass, it is possible to form the substrate unit 210 and the protruding portion 220 of the sealing unit 200. The substrate unit 210 of the sealing unit 200 includes a third surface 212 and a fourth surface 214. The sealing unit 200 is adhered to the substrate 100 with the adhesive layer 300 therebetween such that the third surface 212 of the substrate unit 210 faces the first surface 102 of the substrate 100. The fourth surface 214 of the substrate unit 210 is on the opposite side to the third surface 212 of the substrate unit 210. The protruding portion 220 of the sealing unit 200 protrudes from the substrate unit 210, specifically, the third surface 212 of the substrate unit 210 toward the substrate 100 in the thickness direction of the substrate unit 210.

For example, as shown in FIG. 2 and FIG. 3, in a portion of the sealing unit 200 where the recessed portion 222 is not provided, the outer edge 216 of the substrate unit 210 substantially is flush with the outer wall 226 of the protruding portion 220. Therefore, in this portion, it is possible to reduce the manufacturing costs of the sealing unit 200 by the amount which is saved by not providing the recessed portion 222.

Further, as shown in FIG. 2 and FIG. 4, in a portion of the outer edge 216 of the substrate unit 210 of the sealing unit 200 which overlaps the first side 106a, the second side 106b, or the fourth side 106d of the substrate 100, the outer edge 216 of the substrate unit 210 of the sealing unit 200 is substantially flush with the side 106 of the substrate 100. This is due to that the first side 106a, the second side 106b, and the fourth side 106d of the substrate 100, and a portion of the outer edge 216 of the substrate unit 210 of the sealing unit 200 overlapping the first side 106a, the second side 106b, and the fourth side 106d of the substrate 100 are simultaneously cut by scribing. Further, in the portion, the adhesive layer 300 is located inside the outer edge 216 of the substrate unit 210 of sealing unit 200 and the side 106 of the substrate 100. Therefore, it is possible to cause a cutting line not to overlap the adhesive layer 300.

In the present embodiment, for example, as shown in FIGS. 2 to 4, the adhesive layer 300 covers at least a part of the inner wall 228 of the protruding portion 220. Note that the adhesive layer 300 need not cover the inner wall 228 of the protruding portion 220.

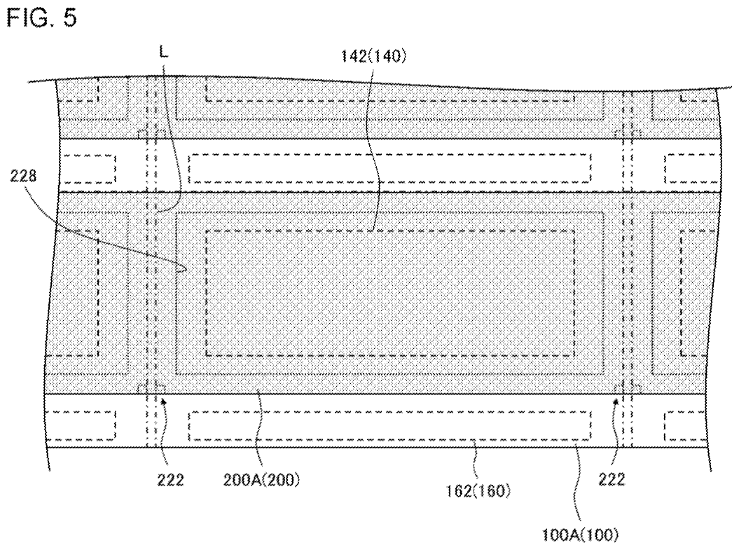

FIG. 5 is a diagram for explaining one example of a method for manufacturing the light-emitting device 10 illustrated in FIGS. 1 to 4.

First, a first base material 100A to be the substrate 100 is prepared. By forming the light-emitting units 140 and the terminals 160, a plurality of light-emitting regions 142 and a plurality of terminal areas 162 are provided on the first base material 100A.

Further, a second base material 200A to be the sealing unit 200 is prepared. A plurality of recessed portions are formed on the opposite side to a surface of the second base material 200A to be the fourth surface 214 of the sealing unit 200. Each of the recessed portions includes the inner wall 228 as an inner-side surface thereof. Further, the recessed portions 222 are formed at portions of the second base material 200A to be the corners of the sealing unit 200 on the terminal area 162 side. Further, a region of the second base material 200A which overlaps the terminal area 162 is removed in advance. Note that the region of the second base material 200A which overlaps the terminal area 162 may be removed, as described later, after the first base material 100A and the second base material 200A are overlapped with the adhesive layer 300 therebetween and, the first base material 100A and the second base material 200A are adhered with the adhesive layer 300 therebetween.

Then, as shown in FIG. 5, the first base material 100A and the second base material 200A are overlapped with the adhesive layer 300 therebetween, and the first base material 100A and the second base material 200A are adhered with the adhesive layer 300 therebetween. Then, by using a scriber, a scribe line is formed along a cutting line L illustrated by a dashed line in FIG. 5. Then, the first base material 100A and the second base material 200A are cut along the scribe line, that is, the cutting line L, and a plurality of substrates 100 and a plurality of sealing units 200 are cut out. Sides of the first base material 100A cut out along the cutting line L are to be the first side 106a, the second side 106b, and the fourth side 106d. In this step, the adhesive layer 300 is arranged not to overlap the cutting line L such that the cutting is not inhibited.

In this manner, the light-emitting device 10 illustrated in FIGS. 1 to 4 is manufactured.

### MODIFICATION EXAMPLE

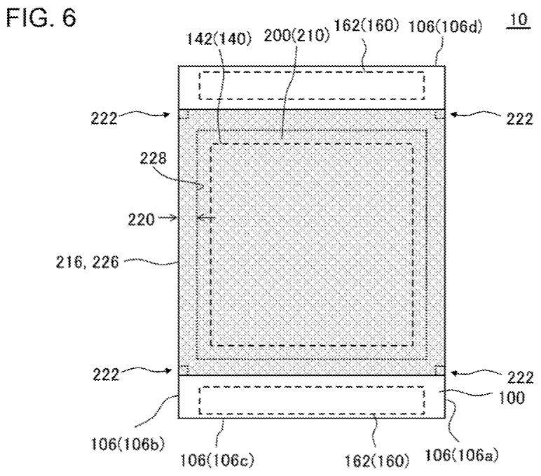

FIG. 6 is a plan view of the light-emitting device 10 according to a modification example. The light-emitting device 10 according to the present modification example is the same as the light-emitting device 10 according to the embodiment, except for the following points.

In the present modification example, the terminal area 162 is provided on both sides of the light-emitting region 142, that is, the third side 106c side and the fourth side 106d side of the substrate 100. For example, in a case where the light-emitting device 10, that is, the light-emitting region 142 is a surface light source, the terminal 160 connected to an anode of the light-emitting unit 140 may be provided on one side of the light-emitting region 142, and the terminal 160 connected to a cathode of the light-emitting unit 140 may be provided on the other side of the light-emitting region 142.

In the present modification example, force is easily added in the thickness direction of the substrate 100 in the terminal areas 162 on both sides of the light-emitting region 142. In this case, as described in the present modification example, the recessed portion 222 may be provided at, of the four corners of the frame shape of the protruding portion 220, both of the two corners on a side with one terminal area 162, that is, the third side 106c side of the substrate 100, and the two corners on a side with the other terminal area 162, that is, the fourth side 106d side of the substrate 100.

Hitherto, the embodiment and examples are described with reference to the drawings. However, these are just examples of the present invention, and various other configurations may be employed.

This application claims priority from Japanese Patent Application No. 2020-037470, filed on Mar. 5, 2020, the disclosure of which is incorporated by reference in its entirety.

### REFERENCE SIGNS LIST

10 light-emitting device
100 substrate
100A first base material
102 first surface
104 second surface
106 side
106a first side
106b second side
106c third side
106d fourth side
140 light-emitting unit
142 light-emitting region
160 terminal
162 terminal area
200 sealing unit
200A second base material
210 substrate unit
212 third surface
214 fourth surface
216 outer edge
220 protruding portion
222 recessed portion
226 outer wall
228 inner wall
300 adhesive layer

1. A light-emitting device comprising:
a substrate;
a light-emitting unit located over the substrate; and
a sealing unit sealing the light-emitting unit, the sealing unit comprising:
a substrate unit; and
a protruding portion which protrudes from the substrate unit toward the substrate, has a frame shape when viewed from a thickness direction of the substrate unit, and is adhered to the substrate with an adhesive layer therebetween,
wherein an outer wall of the protruding portion comprises a recessed portion which is recessed toward an inner wall of the protruding portion relative to an outer edge of the substrate unit, the recessed portion being located at a corner of the frame shape when viewed from the thickness direction of the substrate unit.

2. The light-emitting device according to claim 1,
wherein the adhesive layer covers at least a part of a portion of the outer wall of the protruding portion, the portion being provided with the recessed portion.

3. The light-emitting device according to claim 1,
wherein the corner of the protruding portion in which the recessed portion is provided is located on a side with a region of the substrate in which a terminal connected to the light-emitting unit is arranged.

4. The light-emitting device according to claim 3,
wherein the outer wall of the protruding portion comprises a portion aligned with the outer edge of the substrate unit, the portion being located at another corner of the frame shape located on an opposite side to the region of the substrate in which a terminal connected to the light-emitting unit is arranged when viewed from the thickness direction of the substrate unit.

5. A sealing unit comprising:
a substrate unit; and
a protruding portion which protrudes from the substrate unit toward a thickness direction of the substrate unit and has a frame shape when viewed from the thickness direction of the substrate unit,
wherein an outer wall of the protruding portion comprises a recessed portion which is recessed toward an inner wall side of the protruding portion and is located at a corner of the frame shape when viewed from the thickness direction of the substrate unit.
